(19) United States
(12) Patent Application Publication
(10) Pub. No.: US 2024/0014257 A1
(43) Pub. Date: Jan. 11, 2024

(54) SILICON CARBIDE SEMICONDUCTOR DEVICE

(71) Applicant: FUJI ELECTRIC CO., LTD., Kawasaki-shi (JP)

(72) Inventor: Shinichiro MATSUNAGA, Matsumoto-city (JP)

(73) Assignee: FUJI ELECTRIC CO., LTD., Kawasaki-shi (JP)

(21) Appl. No.: 18/324,936

(22) Filed: May 26, 2023

(30) Foreign Application Priority Data
Jul. 11, 2022 (JP) 2022-111432

(51) Int. Cl. H01L 29/06; H01L 29/16; H01L 29/78

(52) U.S. Cl. CPC H01L 29/063; H01L 29/1608; H01L 29/7813

(57) ABSTRACT

Between the front surface of a semiconductor substrate and an n⁻-type drift region, a p⁺⁺-type contact region, a p-type base region, a p⁺-type high-concentration region, and an n-type current spreading region are provided directly beneath a gate pad, sequentially from a front side of the semiconductor substrate so as to face an entire surface of a gate pad, via a field oxide film. The high-concentration region is electrically connected to source electrode wiring via a p⁺⁺-type wiring region. N⁺-type regions that are electrically floating (or n⁺-type wiring regions of the source potential) are selectively provided between the front surface of the semiconductor substrate and the contact region. The n⁺-type regions have a function of drawing out holes in the high-concentration region and discharging the holes to the source electrode, when the voltage applied to the drain electrode rapidly increases with respect to the potential of the source electrode.

### CROSS REFERENCE TO RELATED APPLICATIONS

This application is based upon and claims the benefit of priority of the prior Japanese Patent Application No. 2022-111432, filed on Jul. 11, 2022, the entire contents of which are incorporated herein by reference.

### BACKGROUND OF THE INVENTION

### 1. Field of the Invention

Embodiments of the invention relate to a silicon carbide semiconductor device.

### 2. Description of the Related Art

A commonly known structure of a silicon carbide metal oxide semiconductor field effect transistor (SiC-MOSFET) containing silicon carbide (SiC) as a semiconductor material and having a three-layer structure including a metal, an oxide film, and a semiconductor, directly beneath a gate pad, has a p⁺-type high-concentration region between a p-type base region and an n⁻-type drift region (for example, refer to International Publication No. WO 2018/055719, Japanese Laid-Open Patent Publication No. 2017-005278, and Japanese Laid-Open Patent Publication No. 2015-211159). The p⁺-type high-concentration region directly beneath the gate pad has a function of suppressing increases in the potential of regions directly beneath the gate pad caused by steep increases in the voltage applied to a drain electrode.

A structure of a conventional silicon carbide semiconductor device is described. FIG. 7 is a cross-sectional view depicting the structure of the conventional silicon carbide semiconductor device. A conventional silicon carbide semiconductor device 110 depicted in FIG. 7 is a SiC-MOSFET that has a source electrode (not depicted) and a gate pad 114 provided apart from each other at a front surface of a semiconductor substrate 111, in an active region. Directly beneath the source electrode, a predetermined MOS gate structure (not depicted) is provided in the semiconductor substrate 111, at the front surface thereof. The source electrode is electrically connected to n⁺-type source regions and a p⁺⁺-type contact region 106 that configure the MOS gate structure.

The gate pad 114 is provided on the front surface of the semiconductor substrate 111, via a field oxide film 112. The gate pad 114 has a relatively large area (surface area) for bonding wiring that is for applying gate voltage. Gate electrodes configuring the MOS gates are electrically connected to the gate pad 114. Directly beneath the gate pad 114, the p-type base region 104 and the p⁺⁺-type contact region 106 are provided between the front surface of the semiconductor substrate 111 and an n⁻-type drift region 101, similarly to the MOS gate structure directly beneath the source electrode. Directly beneath the gate pad 114 is free of the n⁺-type source regions.

The p⁺⁺-type contact region 106 directly beneath the gate pad 114 faces an entire surface of the gate pad 114 via the field oxide film 112, is in contact with the field oxide film 112 at the front surface of the semiconductor substrate 111, and is in contact with source electrode wiring 113a in a vicinity of an end of the gate pad 11. The p-type base region 104 directly beneath the gate pad 114 is provided between the p⁺⁺-type contact region 106 and the n⁻-type drift region 101 and is in contact with the p⁺⁺-type contact region 106. An n-type current spreading region 102 is provided between the p-type base region 104 and the n⁻-type drift region 101 and is in contact with the n⁻-type drift region 101.

A p⁺-type high-concentration region 103 is provided between and in contact with the n-type current spreading region 102 and the p-type base region 104 directly beneath the gate pad 114. The p⁺-type high-concentration region 103 is electrically connected to the source electrode wiring 113a via a later-described p⁺⁺-type wiring region 105 and is not directly connected to the source electrode or the source electrode wiring 113a. The p⁺-type high-concentration region 103 depletes when voltage that is positive with respect to the source electrode is applied to a drain electrode 115 and has a function of fixing a pn junction 108, which is formed with the n-type current spreading region 102, to the potential (source potential: normally, the ground potential) of the source electrode.

The p⁺⁺-type wiring region 105 is disposed in the vicinity of the end of the gate pad 114 and is directly connected to the source electrode wiring 113a or is electrically connected to the source electrode wiring 113a via the p⁺⁺-type contact region 106. The p⁺⁺-type wiring region 105 has a function of fixing the p⁺-type high-concentration region 103 to the potential of the source electrode. The source electrode wiring 113a is coupled to the source electrode by a non-depicted portion. An n⁺-type drain region 109 is provided between a back surface of the semiconductor substrate 111 and the n⁻-type drift region 101. In an entire area of the back surface of the semiconductor substrate 111, the drain electrode 115 is provided in contact with the n⁺-type drain region 109.

In the conventional silicon carbide semiconductor device 110 described above, when voltage that is positive with respect to the source electrode is applied to the drain electrode 115, the pn junction 108 between the p⁺-type high-concentration region 103 and the n-type current spreading region 102 is reverse biased, whereby in a vicinity of the pn junction 108, acceptors in the p⁺-type high-concentration region 103 and donors in the n-type current spreading region 102 are ionized, and a depletion layer is formed at the pn junction 108 by both of these ions. This depletion layer (static capacitance) fixes the pn junction 108 between the p⁺-type high-concentration region 103 and the n-type current spreading region 102 to the potential of the source electrode and bears the high voltage applied to the drain electrode 115.

As for a conventional silicon carbide semiconductor device, a device has been proposed in which an n⁺-type wiring region that is fixed to the potential of the source electrode is provided between the front surface of the semiconductor substrate and a p⁺⁺-type wiring region for fixing the source potential; the n⁺-type wiring region faces an entire area of the gate pad in a depth direction (for example, refer to Japanese Laid-Open Patent Publication No. 2015-211159, Japanese Patent No. 6840300, and Nagahisa, Y., et al, “Novel Termination Structure Eliminating Bipolar Degradation of SBD-embedded SiC-MOSFET”, Proceedings of the 202032nd International Symposium on Power Semiconductor Devices and ICs: ISPSD2020, Austria, IEEE, September 2020, pp. 114-117). The n⁺-type wiring region has a function of drawing out displacement current that occurs in a region directly beneath the gate pad due to a steep rise in the voltage applied to the drain electrode. Further, even when the voltage applied to the drain electrode increases steeply, the n⁺-type wiring region maintains the potential of the source electrode without depleting and has a function of suppressing increases in the potential of the region directly beneath the gate pad.

FIG. 8 is a cross-sectional view depicting another example of a structure of the conventional silicon carbide semiconductor device. FIG. 9 is a plan view depicting a layout when the region directly beneath the gate pad in FIG. 8 is viewed from a front side of the semiconductor substrate. FIG. 9 depicts a layout of a contour (thick dashed line) of the gate pad 114, the p-type base region 104, the p⁺⁺-type wiring region 105, and an n⁺-type wiring region 121 (hatched portion). Further, in FIG. 9, in the depicted contour of the p⁺⁺-type wiring region 105, a portion facing the n⁺-type wiring region 121 in the depth direction is indicated by a dashed line. FIGS. 8 and 9 correspond to the structure of the portion directly beneath the gate pad depicted in Japanese Laid-Open Patent Publication No. 2015-211159, Japanese Patent No. 6840300, and Nagahisa, Y., et al, “Novel Termination Structure Eliminating Bipolar Degradation of SBD-embedded SiC-MOSFET”.

A conventional silicon carbide semiconductor device 120 depicted in FIGS. 8 and 9 differ from the conventional silicon carbide semiconductor device 110 depicted in FIG. 7 in that directly beneath the gate pad 114, instead of the p⁺⁺-type contact region (reference numeral 106 in FIG. 7), the n⁺-type wiring region 121 for drawing out current and fixing the source potential is provided. Between the front surface of the semiconductor substrate 111 and the p-type base region 104, the n⁺-type wiring region 121 is in contact with the field oxide film 112 and the p-type base region 104 and facing an entire surface of the gate pad 114 in the depth direction. The n⁺-type wiring region 121 is directly connected to the source electrode wiring 113a and is fixed to the potential of the source electrode.

### SUMMARY OF THE INVENTION

According to an embodiment of the invention, a silicon carbide semiconductor device includes: an insulated gate having a metal-oxide-semiconductor structure; a semiconductor substrate containing silicon carbide and having a first main surface and a second main surface that are opposite to each other; a first semiconductor region of a first conductivity type, provided in the semiconductor substrate; a second semiconductor region of a second conductivity type, provided between the first main surface of the semiconductor substrate and the first semiconductor region; a third semiconductor region of the second conductivity type, selectively provided between the first main surface of the semiconductor substrate and the second semiconductor region, the third semiconductor region having an impurity concentration that is higher than an impurity concentration of the second semiconductor region; a device structure having the insulated gate, wherein a current that passes through a pn junction between the second semiconductor region and the first semiconductor region flows in the device structure; a gate pad provided at the first main surface of the semiconductor substrate via an insulating film, the gate pad being electrically connected to a gate electrode constituting the metal of the insulated gate, an entire surface of the gate pad facing the third semiconductor region via the insulating film; a first electrode provided at the first main surface of the semiconductor substrate, apart from the gate pad, the first electrode being electrically connected to the second semiconductor region and the third semiconductor region; a second electrode provided at the second main surface of the semiconductor substrate; a fourth semiconductor region of the second conductivity type, provided between the second semiconductor region and the first semiconductor region, the fourth semiconductor region facing the gate pad in a depth direction of the semiconductor device, and having an impurity concentration that is higher than the impurity concentration of the second semiconductor region and lower than the impurity concentration of the third semiconductor region; a fifth semiconductor region of the second conductivity type, penetrating through the second semiconductor region in the depth direction of the semiconductor device and reaching the fourth semiconductor region, the fifth semiconductor region electrically connecting the first electrode to the fourth semiconductor region, and having an impurity concentration that is higher than the impurity concentration of the fourth semiconductor region; and a plurality of sixth semiconductor regions of the first conductivity type, selectively provided between the first main surface of the semiconductor substrate and the third semiconductor region, each sixth semiconductor region facing the gate pad in the depth direction of the device.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a silicon carbide semiconductor device according to a first embodiment is viewed from a front side of a semiconductor substrate thereof.

FIG. 2 is a cross-sectional view depicting the structure along cutting line A-A′ in FIG. 1.

FIG. 3 is a cross-sectional view depicting the structure along cutting line B-B′ in FIG. 1.

FIG. 4 is a plan view depicting the layout when regions directly beneath a gate pad in FIG. 2 are viewed from the front side of the semiconductor substrate.

FIG. 5 is a cross-sectional view depicting a structure of a silicon carbide semiconductor device according to a second embodiment.

FIG. 6 is a plan view depicting a layout when a region directly beneath the gate pad in FIG. 5 is viewed from the front side of the semiconductor substrate.

FIG. 7 is a cross-sectional view depicting a structure of a conventional silicon carbide semiconductor device.

FIG. 8 is a cross-sectional view depicting another example of a structure of the conventional silicon carbide semiconductor device.

FIG. 9 is a plan view depicting a layout when a region directly beneath a gate pad in FIG. 8 is viewed from a front side of the semiconductor substrate.

### DETAILED DESCRIPTION OF THE INVENTION

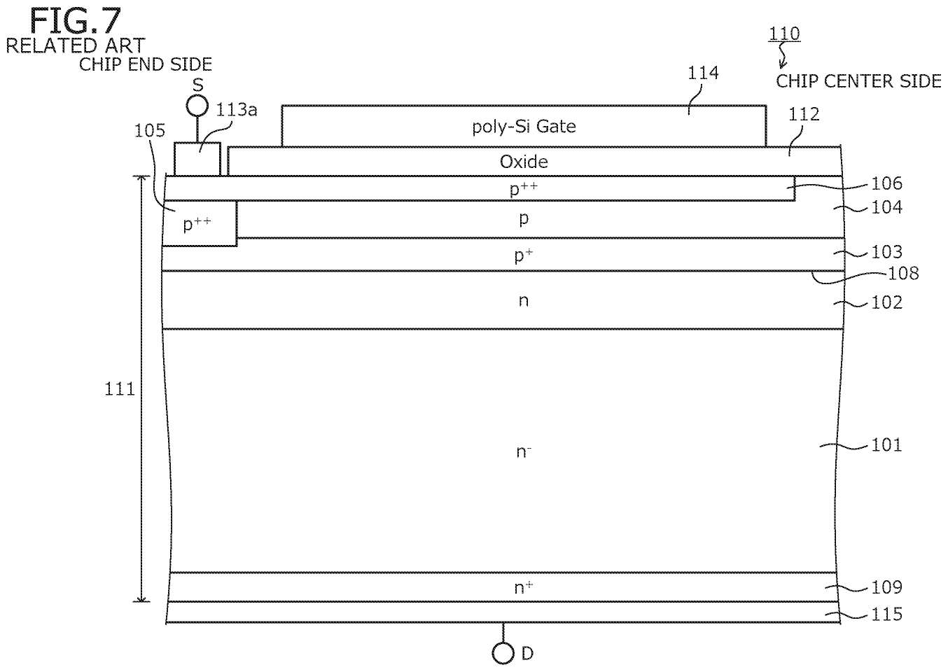

First, problems associated with the conventional technique are discussed. In the conventional silicon carbide semiconductor device 110 (refer to FIG. 7), holes in the p⁺-type high-concentration region 103 move in the p⁺-type high-concentration region 103 to the p⁺⁺-type wiring region 105 and are drawn out to the source electrode wiring 113a, whereby acceptors in the p⁺-type high-concentration region 103 are ionized, and a depletion layer is formed in a vicinity of the pn junction 108 between the p⁺-type high-concentration region 103 and the n-type current spreading region 102. Nonetheless, in general, p-type regions have a deep energy level and a high resistance value as compared to the source electrode wiring 113a (resistance of metal). Thus, in an instance in which the p⁺-type high-concentration region 103 extends away from a point of connection thereof with the p⁺⁺-type wiring region 105, in a direction parallel to the front surface of the semiconductor substrate 111, when the depletion layer is formed in the vicinity of the pn junction 108, the distance that the holes flowing in the p⁺-type high-concentration region 103 move increases and the potential of the p⁺-type high-concentration region 103 is increased.

Further, the faster (for example, about 20 kV/μs or greater) the voltage applied to the drain electrode 115 is allowed to increase (for example, increase from 0V to 1000V), the greater the amount of current per unit time is for the hole current that is drawn out from the p⁺-type high-concentration region 103 to the source electrode wiring 113a and thus, the hole current flowing through the p⁺-type high-concentration region 103 becomes a large current. Nonetheless, as described above, the p⁺-type high-concentration region 103, which has a deep energy level, has high resistance and therefore, the speed of the depletion of the p⁺-type high-concentration region 103 decreases, whereby the depletion of the p⁺-type high-concentration region 103 does not meet the rapid increase in the voltage applied to the drain electrode 115 and the high voltage applied to the drain electrode 115 is propagated as is beyond the pn junction 108 to the gate pad 114. In this instance, only the p⁺⁺-type wiring region 105 for fixing the source potential is fixed to the potential of the source electrode.

As a result, the potential of the region directly beneath the gate pad 114 becomes large with respect to the p⁺⁺-type wiring region 105, which is fixed to the potential of the source electrode, and high electric field is applied to the field oxide film 112 directly beneath a gate runner, the gate pad 114, etc. Breakdown voltage of the field oxide film 112 is relatively low and withstands 100V to 200V. Thus, dielectric breakdown of the field oxide film 112 may occur due to the high electric field applied to the field oxide film 112. In particular, under subzero temperature environments (for example, less than −40 degrees C. to about −55 degrees C.), as compared to under a normal temperature (for example, 25 degrees C.) environment, the behavior of holes in p-type regions slows and the resistance value of the p-type regions increases by about two times to three times. Thus, the problem described above becomes remarkable due to a rapid rise in the voltage applied to the drain electrode 115.

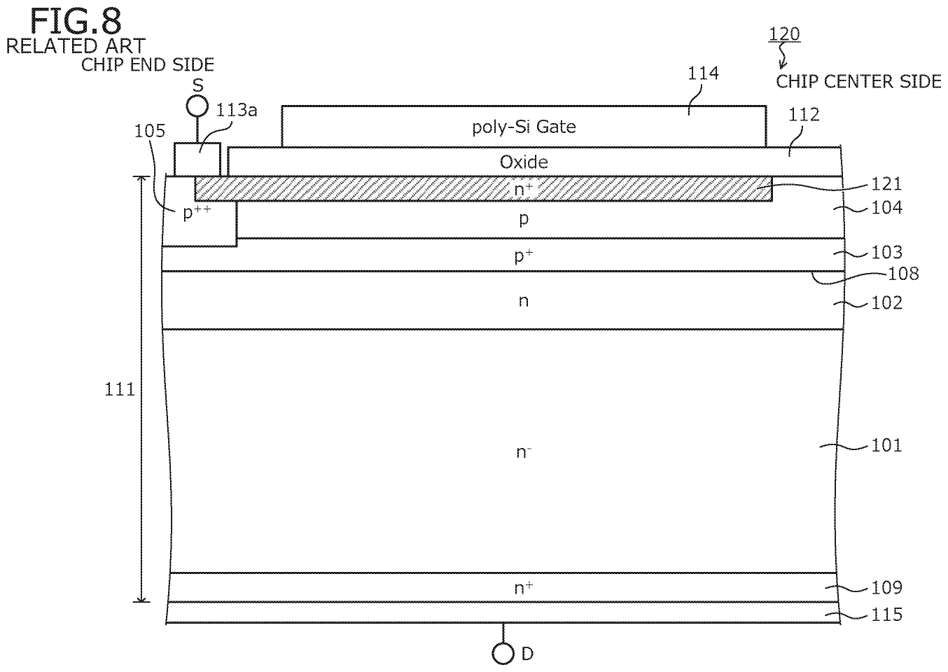

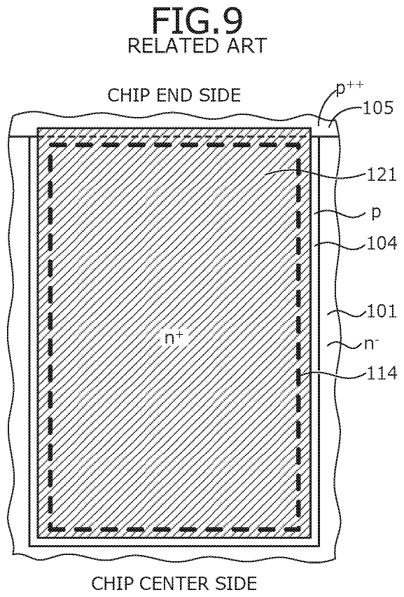

In Japanese Laid-Open Patent Publication No. 2015-211159, when the voltage applied to the drain electrode is increased rapidly, substantially no p-type region is present between the n⁻-type drift region and the n⁺-type wiring region directly beneath the gate pad and punch-through occurs in the n⁺-type wiring region. In the conventional silicon carbide semiconductor device 120 described above (refer to FIGS. 8 and 9) and in that described in Japanese Patent No. 6840300 and that described by Nagahisa, Y., et al, “Novel Termination Structure Eliminating Bipolar Degradation of SBD-embedded SiC-MOSFET”, when the voltage applied to the drain electrode 115 is rapidly increased, punch-through occurs in the n⁺-type wiring region 121 directly beneath the gate pad 114. Thus, shoot-through current flows between the drain electrode 115 and the source electrode wiring 113a, via the n⁺-type wiring region 121. Further, International Publication No. WO 2018/055719, Japanese Laid-Open Patent Publication No. 2017-005278, Japanese Laid-Open Patent Publication No. 2015-216400, Japanese Laid-Open Patent Publication No. 2015-211159, Japanese Patent No. 6840300, and Nagahisa, Y., et al, “Novel Termination Structure Eliminating Bipolar Degradation of SBD-embedded SiC-MOSFET” are silent regarding operation under subzero temperature environments.

Embodiments of a silicon carbide semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical will be given the same reference numerals and will not be repeatedly described.

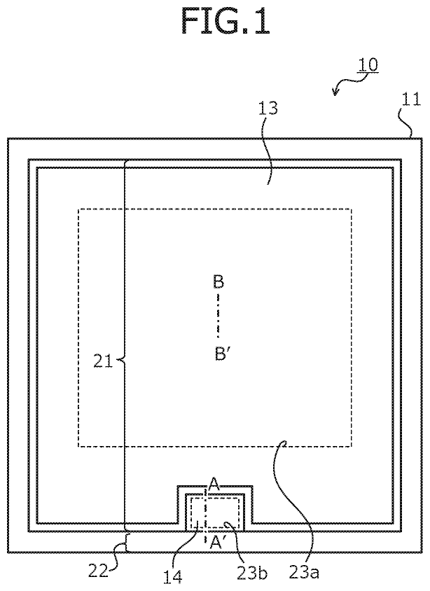

A structure of a silicon carbide semiconductor device according to a first embodiment is described. FIG. 1 is a plan view depicting a layout when the silicon carbide semiconductor device according to the first embodiment is viewed from a front side of a semiconductor substrate thereof. FIG. 1 depicts a layout of a source electrode 13 and a gate pad 14. A silicon carbide semiconductor device 10 according to the first embodiment depicted in FIG. 1 is a vertical SiC-MOSFET that has, in a semiconductor substrate (semiconductor chip) 11 thereof that contains silicon carbide (SiC), a predetermined MOS gate structure (device structure: insulated gate having a three-layer structure including a metal, an oxide film, and a semiconductor) at a front surface of the semiconductor substrate 11, in an active region 21.

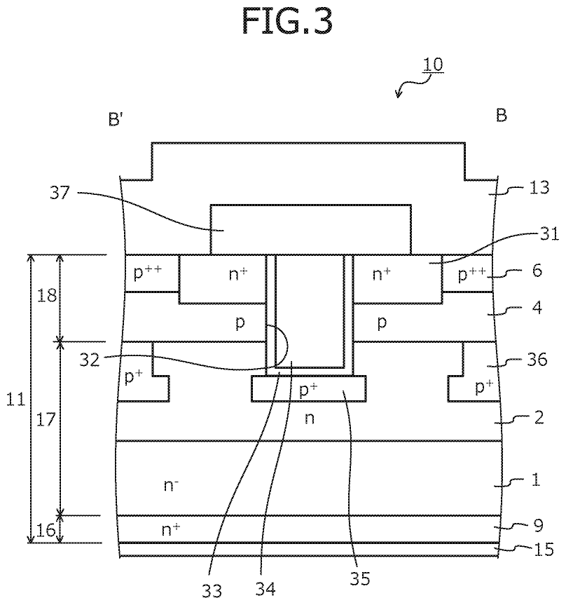

The active region 21 is a region through which a main current (drift current) flows in a direction orthogonal to the front surface of the semiconductor substrate 11 when the silicon carbide semiconductor device 10 (SiC-MOSFET) is on. In the active region 21, multiple unit cells (functional units of the device, in FIG. 3, one unit cell is depicted) each having the same SiC-MOSFET structure are disposed adjacently to one another. The active region 21 has, for example, a substantially rectangular shape in a plan view and is provided in substantially a center (chip center) of the semiconductor substrate 11. An edge termination region 22 is a region between the active region 21 and an end (chip end) of the semiconductor substrate 11.

The edge termination region 22 surrounds a periphery of the active region 21. The edge termination region 22 has a function of mitigating electric field applied to the front side of the semiconductor substrate 11 and sustaining a breakdown voltage. The breakdown voltage is a voltage limit at which no malfunction or destruction of the silicon carbide semiconductor device 10 occurs by a voltage used. In the edge termination region 22, for example, a voltage withstanding structure (not depicted) such as a field limiting ring (FLR), a junction termination extension (JTE) structure, etc. is provided.

In the active region 21, at the front surface of the semiconductor substrate 11, the source electrode (first electrode) 13 and the gate pad (electrode pad) 14 are provided apart from each other. The front surface of the semiconductor substrate 11 is covered by and protected by a passivation film (not depicted). In the passivation film, openings 23a, 23b that expose the source electrode 13 and the gate pad 14, respectively, are provided. In the openings 23a, 23b of the passivation film, different bonding wires (not depicted) are bonded to the source electrode 13 and the gate pad 14, respectively.

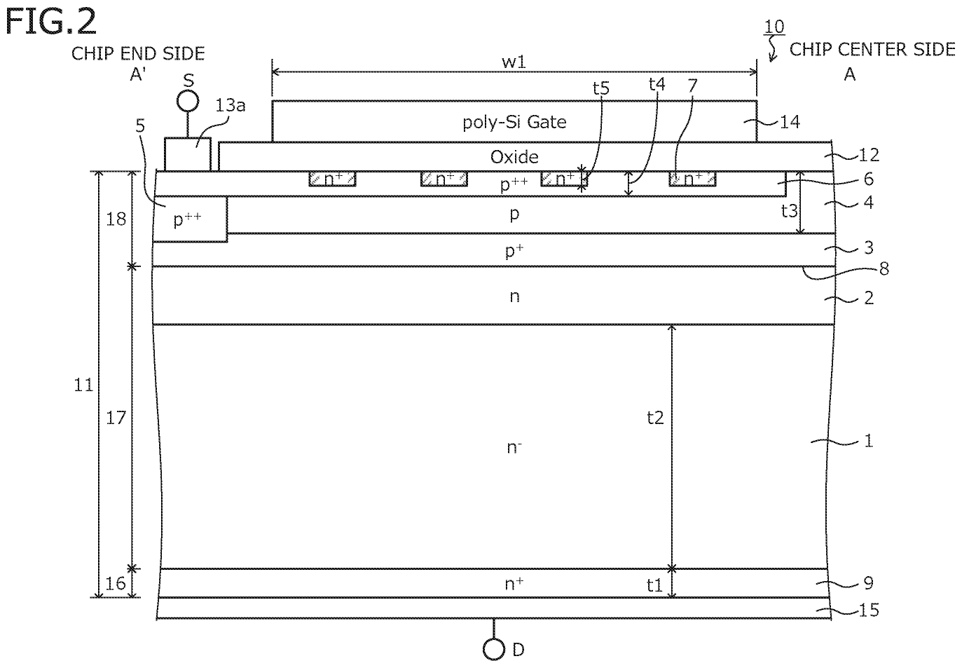

A portion of the source electrode 13 exposed in the opening 23a of the passivation film functions as a source pad (electrode pad). The source electrode 13 covers substantially an entire surface of the active region 21 excluding a region in which the gate pad 14 is disposed. The source electrode 13 has, for example, in a plan view, a substantially rectangular shape of a size substantially equal to that of the active region 21 and a portion thereof is recessed toward the chip center. The source electrode 13, at the front surface of the semiconductor substrate 11, is in ohmic contact with later-described n⁺-type source regions 31 and a p⁺⁺-type contact region 6 (refer to FIGS. 2 to 4).

The gate pad 14 has, for example, a substantially rectangular shape in a plan view and is disposed in a recessed portion of the source electrode 13 with three sides thereof being surrounded by the source electrode 13. The gate pad 14 and all gate electrodes 34 of the SiC-MOSFET are electrically connected via a non-depicted gate runner (refer to FIG. 3). The gate runner surrounds the periphery of the active region 21 or the periphery of the gate pad 14 and has a single-layer structure including the gate metal wiring layer at a same level as that of the source electrode 13 or a stacked structure in which a gate polysilicon (poly-Si) wiring layer and the gate metal wiring layer are sequentially stacked on a later-described field oxide film (insulating film) 12 (refer to FIG. 2).

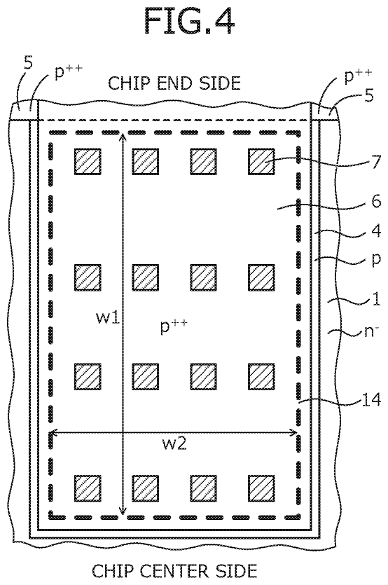

A cross-section of the structure of the silicon carbide semiconductor device 10 according to the first embodiment and a layout of regions directly beneath (side facing an n⁺-type drain region 9) the gate pad 14 are described. FIGS. 2 and 3 are cross-sectional views depicting the structure along cutting line A-A′ and cutting line B-B′ in FIG. 1, respectively. FIG. 4 is a plan view depicting the layout when the regions directly beneath the gate pad in FIG. 2 are viewed from the front side of the semiconductor substrate. In FIGS. 3 and 4, while a relative ratio of thicknesses of portions differs, portions with the same reference numeral have the same thickness. FIG. 4 depicts a layout of a contour (thick dashed line) of the gate pad 14, a p-type base region 4, a p⁺⁺-type wiring region 5, and n⁺-type regions 7 (hatched portions).

The semiconductor substrate 11 is an epitaxial substrate in which epitaxial layers 17, 18 constituting an n⁻-type drift region (first semiconductor region) 1 and the p-type base region (second semiconductor region) 4 are sequentially grown on a front surface of an n⁺-type starting substrate 16 that contains silicon carbide. The semiconductor substrate 11 has, as the front surface, a main surface that has the p-type epitaxial layer 18 and as the back surface, a main surface that has the n⁺-type starting substrate 16. A portion of the p-type epitaxial layer 18 in the edge termination region 22 is removed (not depicted), whereby the front surface of the semiconductor substrate 11 in the edge termination region 22 is the surface of the n⁻-type epitaxial layer 17.

Directly beneath the source electrode 13, a predetermined MOS gate structure is provided in the semiconductor substrate 11, at the front surface thereof. The MOS gate structure, for example, is a trench gate structure configured by the p-type base region 4, the n⁺-type source regions 31, the p⁺⁺-type contact region (third semiconductor region) 6, gate trenches 32, gate insulating films 33, and the gate electrodes 34 (refer to FIG. 3). The trench gate structure is a structure in which the gate electrodes 34 (MOS gates) are embedded in the gate trenches 32 formed in the semiconductor substrate 11, via the gate insulating films 33.

The gate insulating films 33 are in contact with portions (later-described channel forming regions) of the p-type base region 4, between the n⁺-type source regions 31 and the n⁻-type drift region 1. The gate electrodes 34 are provided facing the p-type base region 4 with the gate insulating films 33 intervening therebetween. The gate trenches 32 penetrate through the n⁺-type source regions 31 and the p-type base region 4 from the front surface of the semiconductor substrate 11, in the depth direction, and reach a later-described n-type current spreading region 2. The MOS gate structure may have a planar gate structure in which the MOS gates are provided in plate-like shapes on the semiconductor substrate 11.

An interlayer insulating film 37 is provided in an entire area of the front surface of the semiconductor substrate 11 and covers the gate electrodes 34. The source electrode 13 is provided on the interlayer insulating film 37 and via contact holes in the interlayer insulating film 37, is electrically connected to the n⁺-type source regions 31 and the p⁺⁺-type contact region 6 that configure the MOS gate structure. The n⁺-type starting substrate 16 constitutes the n⁺-type drain region 9. A drain electrode (second electrode) 15 is provided in an entire area of the back surface (back surface of the n⁺-type starting substrate 16) of the semiconductor substrate 11 and is in contact with the n⁺-type drain region 9.

The n⁻-type drift region 1 is provided between the front surface of the semiconductor substrate 11 and the n⁺-type drain region 9 and is in contact with the n⁺-type drain region 9. The n⁻-type drift region 1 is a portion of the n⁻-type epitaxial layer 17, free of ion implantation and left having the n-type impurity concentration at the time of epitaxial growth thereof (that is, for example, a portion excluding diffused regions such as the later-described n-type current spreading region 2); the n⁻-type drift region 1 extends having substantially a constant thickness from the active region 21 to the chip end. A substantially constant thickness means a constant thickness within a range that includes an allowable error due to process variation.

The p-type base region 4 is provided between the front surface of the semiconductor substrate 11 and the n⁻-type drift region 1. The p-type base region 4 is a portion of the p-type epitaxial layer 18, excluding other diffused regions formed by ion implantation in the p-type epitaxial layer 18 (for example, a portion excluding the n⁺-type source regions 31, the p⁺⁺-type contact region 6, a later-described p⁺-type high-concentration region (fourth semiconductor region) 3, the p⁺⁺-type wiring region (fifth semiconductor region) 5, and the n⁺-type regions (sixth semiconductor regions) 7). In the p-type base region 4, a p-type region for adjusting the gate threshold voltage is ion-implanted.

The p-type base region 4 is provided in substantially an entire area of the active region 21. The p-type base region 4 is electrically connected to the source electrode 13 via the n⁺-type source regions 31 and the p⁺⁺-type contact region 6. The p-type base region 4 may be disposed scattered directly beneath the source electrode 13 and directly beneath the gate pad 14. In this instance, the p-type base region 4 directly beneath the gate pad 14 suffices to be electrically connected to the source electrode 13; the scattered p-type base regions 4 may be apart from each other or may be partially connected.

Between the front surface of the semiconductor substrate 11 and the p-type base region 4, the n⁺-type source regions 31 and the p⁺⁺-type contact region 6 are each selectively provided in contact with the p-type base region 4. The n⁺-type source regions 31 and the p⁺⁺-type contact region 6 are exposed at the front surface of the semiconductor substrate 11 and are in ohmic contact with the source electrode 13, at the front surface of the semiconductor substrate 11. The n⁺-type source regions 31 are provided only directly beneath the source electrode 13. The p⁺⁺-type contact region 6 is provided directly beneath the source electrode 13 and directly beneath the gate pad 14.

Directly beneath the source electrode 13, the n-type current spreading region 2 is provided between and in contact with the p-type base region 4 and the n⁻-type drift region 1. The n-type current spreading region 2 is a so-called current spreading layer (CSL) that reduces carrier spreading resistance. The n-type current spreading region 2 is provided in an entire area of the active region 21. The n-type current spreading region 2 may be omitted. In this instance, the n⁻-type drift region 1 and the p-type base region 4 are adjacent to each other in the depth direction.

The gate pad 14 is an electrode pad having, as a lowermost layer thereof, a gate polysilicon electrode layer provided on the front surface of the semiconductor substrate 11 via the field oxide film 12 and, for example, has stacked structure in which the gate polysilicon electrode layer and a gate metal electrode layer (not depicted) of a same level as that of the source electrode 13 are sequentially stacked. The gate metal electrode layer constituting an uppermost surface of the gate pad 14 is exposed in the opening 23b of the passivation film. The gate pad 14 is electrically insulated from the source electrode 13 and source electrode wiring (first electrode) 13a by the interlayer insulating film 37 (not depicted in FIG. 2).

The gate pad 14 is electrically insulated from the semiconductor substrate 11 by the field oxide film 12. The field oxide film 12 has a thickness at least enabling electrical insulation between the gate pad 14 and the semiconductor substrate 11. A greater is the thickness of the field oxide film 12, the higher is the dielectric withstanding voltage of the field oxide film 12. Between the front surface of the semiconductor substrate 11 and the n⁻-type drift region 1, the n-type current spreading region 2, the p-type base region 4, and the p⁺⁺-type contact region 6 are provided directly beneath the gate pad 14, as similarly provided directly beneath the source electrode 13.

The p⁺⁺-type contact region 6 directly beneath the gate pad 14 is in contact with the field oxide film 12 at the front surface of the semiconductor substrate 11 and faces an entire surface of the gate pad 14 with the field oxide film 12 intervening therebetween. The p⁺⁺-type contact region 6 directly beneath the gate pad 14 is directly connected to the later-described source electrode 13 (refer to FIG. 1) or the source electrode wiring 13a via a contact hole of the interlayer insulating film 37, or is electrically connected to the source electrode wiring 13a via the later-described p⁺⁺-type wiring region 5.

The p-type base region 4 directly beneath the gate pad 14 is provided between the p⁺⁺-type contact region 6 and the n⁻-type drift region 1 and is in contact with the p⁺⁺-type contact region 6. Between the p-type base region 4 and the n⁻-type drift region 1, the n-type current spreading region 2 is provided directly beneath the gate pad 14 and is in contact with the n⁻-type drift region 1. The p⁺-type high-concentration region 3 is provided between and in contact with the p-type base region 4 directly beneath the gate pad 14 and the n-type current spreading region 2.

The p⁺-type high-concentration region 3 is electrically connected to the source electrode wiring 13a via the later-described p⁺⁺-type wiring region 5. The p⁺-type high-concentration region 3 is apart from the source electrode 13 and the source electrode wiring 13a. The p⁺-type high-concentration region 3 has a function of fixing the pn junction 8 to the potential (source potential: normally, the ground potential) of the source electrode 13 by discharging holes and depleting, when a pn junction 8 between the p⁺-type high-concentration region 3 and the n-type current spreading region 2 is reverse biased.

The p⁺-type high-concentration region 3, for example, may be formed concurrently with p⁺-type regions 35, 36 that are for mitigating electric field applied to the gate insulating films 33 at inner walls of the gate trenches 32. For example, the p⁺-type regions 35 are formed between the p-type base region 4 and the n⁻-type drift region 1 and face bottoms of the gate trenches 32. Each of the p⁺-type regions 36 is selectively formed between an adjacent two of the gate trenches 32, between the p-type base region 4 and the n⁻-type drift region 1, and is in contact with these region and the n-type current spreading region 2.

The p⁺⁺-type wiring region 5 is disposed in a vicinity of an end of the gate pad 14. The p⁺⁺-type wiring region 5 is directly in contact with the source electrode wiring 13a via a contact hole of the interlayer insulating film 37 (not depicted) or is electrically connected to the source electrode wiring 13a via the p⁺⁺-type contact region 6 (refer to FIG. 2). The p⁺⁺-type wiring region 5 penetrates through the p-type base region 4 and reaches the p⁺-type high-concentration region 3 in the depth direction, and electrically connects the p⁺-type high-concentration region 3 and the source electrode wiring 13a.

The source electrode wiring 13a is provided at the same level as that of the source electrode 13 in the vicinity of the end of the gate pad 14 and faces the p⁺⁺-type wiring region 5 in the depth direction. The source electrode wiring 13a is coupled to the source electrode 13 by a non-depicted portion. The vicinity of the end of the gate pad 14 is a vicinity of the four sides of the gate pad 14, which has a substantially rectangular shape in a plan view. Thus, the p⁺⁺-type wiring region 5 and the source electrode wiring 13a are disposed between the source electrode 13 and the gate pad 14, or close to one of the four sides of the gate pad 14 not facing the source electrode 13.

The gate metal wiring layer is provided along at least one side of the periphery of the gate pad 14 and thus, the p⁺⁺-type wiring region 5 and the source electrode wiring 13a are suitably disposed at positions so that the source electrode wiring 13a is apart from the gate metal wiring layer. The p⁺⁺-type wiring region 5 may face the p⁺⁺-type contact region 6 in the depth direction. FIGS. 2 and 4 depict an instance in which the p⁺⁺-type wiring region 5 and the source electrode wiring 13a are disposed along one end of the gate pad 14. In FIG. 4, in the depicted contour of the p⁺⁺-type wiring region 5, a portion thereof facing the p⁺⁺-type contact region 6 in the depth direction is indicated by a dashed line.

Further, directly beneath the gate pad 14, the n⁺-type regions 7 are selectively provided between the front surface of the semiconductor substrate 11 and the p⁺⁺-type contact region 6, and are in contact with the field oxide film 12 and the p⁺⁺-type contact region 6. The n⁺-type regions 7 are floating electrically. The n⁺-type regions 7 are, for example, disposed in a matrix-like pattern and peripheries of the n⁺-type regions 7 are surrounded by the p⁺⁺-type contact region 6 having a lattice-like shape. All the n⁺-type regions 7, which are disposed in a matrix-like pattern apart from one another, face the gate pad 14 in the depth direction.

The n⁺-type regions 7 have a function of drawing out holes in the p⁺-type high-concentration region 3, when voltage that is positive with respect to the source electrode 13 is applied to the drain electrode 15 and the pn junction 8 between the p⁺-type high-concentration region 3 and the n-type current spreading region 2 is reverse biased. In particular, when the pn junction 8 is reverse biased, holes in the p⁺-type high-concentration region 3 migrate in the p⁺-type high-concentration region 3 and are drawn out to the source electrode 13 via the p⁺⁺-type wiring region 5 and the source electrode wiring 13a and are further discharged from the p⁺-type high-concentration region 3 and drawn out by closest ones thereto of the n⁺-type regions 7.

The holes are discharged from the p⁺-type high-concentration region 3, whereby in a vicinity of the pn junction 8 between the p⁺-type high-concentration region 3 and the n-type current spreading region 2, acceptors in the p⁺-type high-concentration region 3 are negatively ionized. The holes that are discharged from the p⁺-type high-concentration region 3 and drawn out by the n⁺-type regions 7 recombine with electrons in the n⁺-type regions 7 and are eliminated. Thus, the holes discharged from the p⁺-type high-concentration region 3 are drawn out by the n⁺-type regions 7, whereby ionization of acceptors in the p⁺-type high-concentration region 3 progresses.

The p⁺-type high-concentration region 3 is depleted by the ionization of the acceptors in the p⁺-type high-concentration region 3 and a depletion layer is formed by the pn junction 8 between the p⁺-type high-concentration region 3 and the n-type current spreading region 2. The depletion layer (static capacitance) fixes the pn junction 8 between the p⁺-type high-concentration region 3 and the n-type current spreading region 2 to the potential of the source electrode 13 and bears high voltage (for example, about 1000V or greater) applied to the drain electrode 15. Thus, high voltage applied to the drain electrode 15 may be prevented from propagating beyond the pn junction 8 as is to the gate pad 14.

The holes discharged from the p⁺-type high-concentration region 3 migrate in substantially a vertical direction (direction orthogonal to the front surface of the semiconductor substrate 11) to the closest ones thereto of the n⁺-type regions 7 and are drawn out by the n⁺-type regions 7. Thus, a distance travelled by holes from the p⁺-type high-concentration region 3 to the closest ones thereto of the n⁺-type regions 7 is short, about 1 μm to 2 μm. Thus, even when the voltage applied to the drain electrode 15 rapidly increases by, for example, about 20 kV/μs or greater (in particular, about 50 kV/μs or greater), the holes in the p⁺-type high-concentration region 3 are rapidly discharged and the p⁺-type high-concentration region 3 is rapidly depleted.

Further, when the pn junction 8 between the p⁺-type high-concentration region 3 and the n-type current spreading region 2 is reverse biased, the holes in the p⁺-type high-concentration region 3 are drawn out by the n⁺-type regions 7, whereby the holes that flow in the p⁺-type high-concentration region 3 and are drawn out to the source electrode 13 via the p⁺⁺-type wiring region 5 (or the p⁺⁺-type wiring region 5 and the source electrode wiring 13a) may be suppressed from becoming a large current. As a result, the resistance value of the p⁺-type high-concentration region 3 may be reduced and thus, increases in the potential of the p⁺-type high-concentration region 3 may be suppressed.

The n⁺-type regions 7 are electrically floating and thus, while the p⁺⁺-type contact region 6 directly beneath the gate pad 14 is not fixed to the potential of the source electrode 13 at a portion apart from source potential fixing point during early reverse bias of the pn junction 8, the n⁺-type regions 7 approach the potential of the source electrode 13 overtime and are fixed to the potential of the source electrode 13. The source potential fixing point of the p⁺⁺-type contact region 6 directly beneath the gate pad 1 is a point directly connected to or electrically connected to the source electrode wiring 13a.

As described above, the electrons in the n⁺-type regions 7 recombine with the holes discharged from the p⁺-type high-concentration region 3 and thereby, disappear, whereby in a vicinity of pn junctions between the p⁺⁺-type contact region 6 and the n⁺-type regions 7, donors in the n⁺-type regions 7 are positively ionized and a depletion layer (static capacitance) is formed by the pn junctions. When the static capacitance of this depletion layer is increased, the voltage may be reduced so that the potential directly beneath the gate pad 14 approaches the source potential.

For example, in an instance in which the silicon carbide semiconductor device 10 according to the first embodiment has a breakdown voltage class of a 1000V or greater, a thickness t1 of the n⁺-type drain region 9 is, for example, about 100 μm and a thickness t2 of the n⁻-type drift region 1 is, for example, about 10 μm. The gate pad 14 has, in a plan view, a substantially rectangular shape having widths (lengths of two sides that share one vertex and are orthogonal to each other) w1, w2 that are, for example, in a range of about 100 μm to 500 μm, and the widths w1, w2 of the gate pad 14 are significantly greater than a sum of the thicknesses (=t1+t2) of the n⁻-type drift region 1 and the n⁺-type drain region 9.

The p⁺-type high-concentration region 3 has an effective p-type impurity concentration that is, for example, in an upper range of 10¹⁷/cm³ to 10¹⁸/cm³. Behavior of the holes in the p-type region slows under a subzero temperature (for example, less than about −40 degrees C. to −55 degrees C.) environment and thus, the effective p-type impurity concentration of the p-type region is about two orders of magnitude lower than the actual p-type impurity concentration of the p-type region. Therefore, in an instance in which the silicon carbide semiconductor device according to the first embodiment is operated under a subzero temperature environment, the actual p-type impurity concentration of the p⁺-type high-concentration region 3 may be, for example, about 1×10¹⁹/cm³ or greater.

The effective impurity concentration of the p-type base region 4 is, for example, in an upper range of 10¹⁶/cm³ to 10¹⁷/cm³. A thickness t3 of the p-type base region 4 is, for example, about 1 μm. An effective impurity concentration of the p⁺⁺-type wiring region 5 is on the order of, for example, 10¹⁹/cm³. An effective impurity concentration and thickness t4 of the p⁺⁺-type contact region 6 are, for example, on the order of 10¹⁹/cm³ and about 0.5 μm, respectively. A thickness t5 of the n⁺-type regions 7 is, for example, about 0.3 μm or less and preferably, may be, for example, about 0.2 μm or less.

Operation of the silicon carbide semiconductor device 10 according to the first embodiment is described. When voltage that is positive with respect to the source electrode 13 is applied to the drain electrode 15 and voltage that is at least equal to the gate threshold voltage is applied to the gate electrodes 34, a channel (n-type inversion layer) is formed in portions (portions along the sidewalls of the gate trenches 32) of the p-type base region 4 facing the gate electrodes 34 with the gate insulating films 33 intervening therebetween. As a result, directly beneath the source electrode 13, the main current flows from the n⁺-type drain region 9, through the n⁻-type drift region 1, the n-type current spreading region 2, and the channel, to the n⁺-type source regions 31, whereby the SiC-MOSFET (the silicon carbide semiconductor device 10) turns on.

On the other hand, when voltage that is positive with respect to the source electrode 13 is applied to the drain electrode 15 and voltage that is less than the gate threshold voltage is applied to the gate electrodes 34, the pn junctions between the p⁺⁺-type contact region 6, the p-type base region 4, the n-type current spreading region 2, and the n⁻-type drift region 1 are reverse biased and the SiC-MOSFET maintains the off state. Further, a depletion layer spreads from the pn junctions, through the n⁻-type drift region 1 in a direction from the active region to the chip end (end of the semiconductor substrate). A predetermined breakdown voltage based on the depletion layer width and the dielectric breakdown field strength of silicon carbide may be ensured corresponding to the extent that the depletion layer extends, in a direction to the chip end, in the edge termination region.

Further, when voltage that is positive with respect to the source electrode 13 is applied to the drain electrode 15, the pn junction 8 between the p⁺-type high-concentration region 3 and the n-type current spreading region 2 directly beneath the gate pad 14 is reverse biased. At this time, holes in the p⁺-type high-concentration region 3 move in the p⁺-type high-concentration region 3 and are drawn out to the source electrode 13 via the p⁺⁺-type wiring region 5 and the source electrode wiring 13a and are further drawn out by the closest ones thereto of the n⁺-type regions 7. As a result, the holes are discharged from the p⁺-type high-concentration region 3 and acceptors in the p⁺-type high-concentration region 3 are negatively ionized in a vicinity of the pn junction 8 between the p⁺-type high-concentration region 3 and the n-type current spreading region 2.

The holes that are drawn out by the n⁺-type regions 7 are eliminated by recombining with electrons in the n⁺-type regions 7 and thus, ionization of the acceptors in the p⁺-type high-concentration region 3 progresses due to the recombination in the n⁺-type regions 7. Further, the pn junction 8 between the p⁺-type high-concentration region 3 and the n-type current spreading region 2 is reverse biased, whereby electrons in the n-type current spreading region 2 drawn out to the drain electrode 15 and donors in the n-type current spreading region 2 are positively ionized in a vicinity of the pn junction 8 between the p⁺-type high-concentration region 3 and the n-type current spreading region 2. Due to both of these ionizations, a depletion layer is formed at the pn junction 8 between the p⁺-type high-concentration region 3 and the n-type current spreading region 2.

The depletion layer (static capacitance) formed by the pn junction 8 between the p⁺-type high-concentration region 3 and the n-type current spreading region 2 fixes the pn junction 8 between the p⁺-type high-concentration region 3 and the n-type current spreading region 2 to the potential of the source electrode 13 and bears the high voltage applied to the drain electrode 15. Further, due to the recombination in the n⁺-type regions 7, holes in the p⁺-type high-concentration region 3 are rapidly discharged and the p⁺-type high-concentration region 3 may be rapidly depleted. Thus, even when voltage applied to the drain electrode 15 increases rapidly, the high voltage applied to the drain electrode 15 may be prevented from propagating beyond the pn junction 8 as is to the gate pad 14.

Further, when the pn junction 8 between the p⁺-type high-concentration region 3 and the n-type current spreading region 2 is reversed biased, holes in the p⁺-type high-concentration region 3 are drawn out by the n⁺-type regions 7, whereby even when the p⁺-type high-concentration region 3 extends by a length (in FIGS. 2 and 4, the width w1 or greater) equal to the widths w1, w2 of the gate pad 14 or greater in a direction parallel to the front surface of the semiconductor substrate 11 and away from the point where the p⁺-type high-concentration region 3 is connected to the p⁺⁺-type wiring region 5, hole current that flows in the p⁺-type high-concentration region 3 to the p⁺⁺-type wiring region 5 may be suppressed from becoming a large current. As a result, the resistance value of the p⁺-type high-concentration region 3 may be reduced and thus, even when the voltage applied to the drain electrode 15 increases rapidly due to high-speed switching, increases in the potential of the p⁺-type high-concentration region 3 may be suppressed.

Further, even when dV/dt (voltage variation per unit time of the voltage applied to the drain electrode 15) is steep when the SiC-MOSFET transitions from on to off, displacement current (hole current), which is generated in the n⁻-type drift region 1, flows in the p⁺-type high-concentration region 3 of a high resistance, and is drawn out to the source electrode 13 via the p⁺⁺-type wiring region 5, decreases due to recombination with electrons in the n⁺-type regions 7. Thus, increases in the potential of the p⁺-type high-concentration region 3 due to steep dV/dt occurring when the SiC-MOSFET transitions from on to off may be prevented.

As described above, according to the first embodiment, the n⁺-type regions that are electrically floating are selective disposed directly beneath the gate pad, between the front surface of the semiconductor substrate and the p⁺⁺-type contact region. Thus, when voltage that is positive with respect to the source electrode is applied to the drain electrode, holes in the p⁺-type high-concentration region of a high resistance directly beneath the gate pad recombine with electrons in the n⁺-type regions and are thereby eliminated, whereby ionization of acceptors in the p⁺-type high-concentration region progresses and the p⁺-type high-concentration region may be rapidly depleted.

As a result, even when the voltage applied to the drain electrode rapidly increases due to high-speed switching, steep dV/dt, etc., a depletion layer is formed by the pn junction between the n-type current spreading region and the p⁺-type high-concentration region directly beneath the gate pad, this depletion layer fixes the pn junction to the potential of the source electrode and bears the high voltage applied to the drain electrode. Thus, application of high electric field to the field oxide film as a result of high voltage applied to the drain electrode may be prevented and dielectric breakdown capability may be enhanced, whereby reliability of the silicon carbide semiconductor device is enhanced.

For example, under a subzero temperature (for example, about −55 degrees C.) environment, the behavior of the holes in the p-type regions slows and the resistance value of the p-type regions increases about two times to three times as compared to an instance under a normal (for example, about 25 degrees C.) environment, the resistance value of an n-type region is independent of temperature. Further, the n-type region has an extremely low sheet resistance as compared to the p-type regions. Thus, the device according to the first embodiment is useful in an instance in which, under a subzero temperature environment, the potential difference of the drain electrode with respect to the source electrode rapidly becomes about 1000V or greater, for example, at a rate of about 20 kV/μs or greater (in particular, about 50 kV/μs or greater).

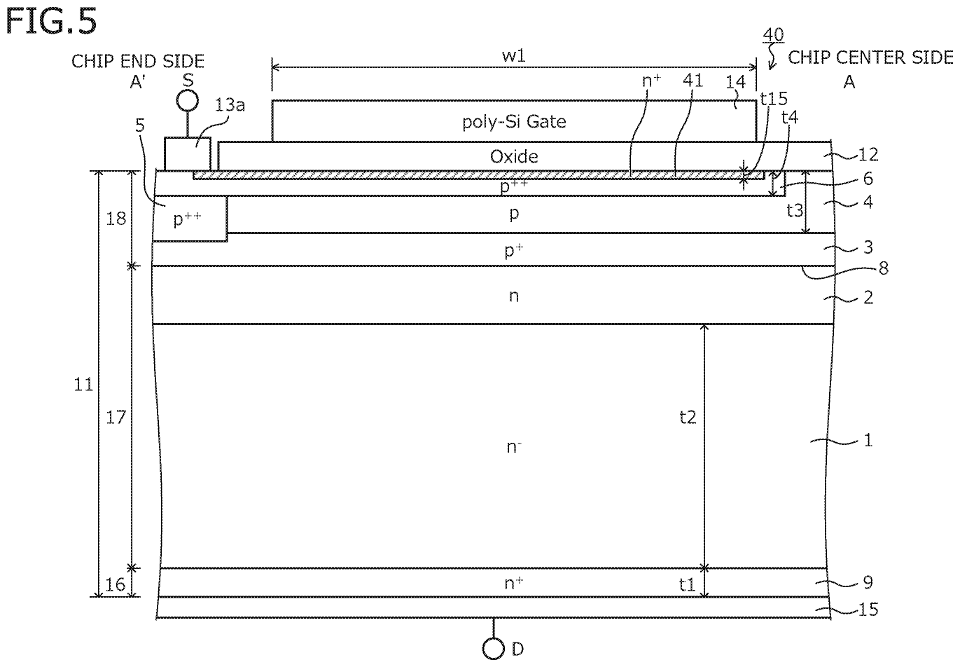

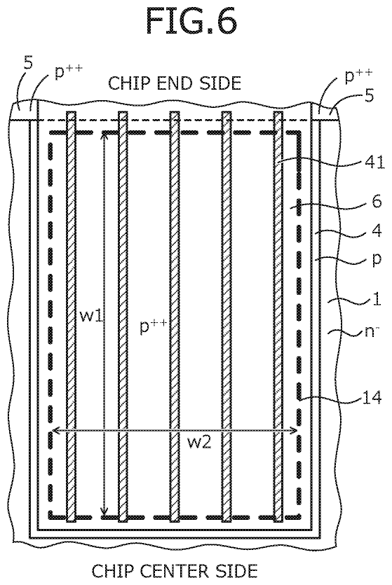

A structure of a silicon carbide semiconductor device according to a second embodiment is described. FIG. 5 is a cross-sectional view depicting the structure of the silicon carbide semiconductor device according to the second embodiment. A layout when a silicon carbide semiconductor device 40 according to the second embodiment is viewed from the front side of the semiconductor substrate 11 thereof and a cross-section of the structure directly beneath the source electrode 13 are the same as those of the first embodiment (refer to FIGS. 1 and 3). FIG. 5 depicts a cross-section of the structure along cutting line A-A′ in FIG. 1. FIG. 6 is a plan view depicting a layout when a region directly beneath the gate pad in FIG. 5 is viewed from the front side of the semiconductor substrate. FIG. 6 depicts a layout of the contour (thick dashed line) of the gate pad 14, the p-type base region 4, the p⁺⁺-type wiring region 5, and n⁺-type wiring regions 41 (hatched portions). Further, in the depicted contour of the p⁺⁺-type wiring region 5, a portion facing the p⁺⁺-type contact region 6 and the n⁺-type wiring regions 41 in the depth direction is indicated by a dashed line.

The silicon carbide semiconductor device 40 according to the second embodiment differs from the silicon carbide semiconductor device according to the first embodiment in that the n⁺-type wiring regions (sixth semiconductor regions) 41 selectively disposed between the front surface of the semiconductor substrate 11 and the p⁺⁺-type contact region 6, directly beneath the gate pad 14, are fixed to the potential of the source electrode 13. In the second embodiment, for example, between the front surface of the semiconductor substrate 11 and the p⁺⁺-type contact region 6, the n⁺-type wiring regions 41 are disposed directly beneath the gate pad 14, in a striped pattern that extends in a direction parallel to the front surface of the semiconductor substrate 11. The n⁺-type wiring regions 41 are directly connected to the source electrode wiring 13a at longitudinal ends thereof and are fixed to the potential of the source electrode 13.

The n⁺-type wiring regions 41 are disposed in a striped pattern, whereby as compared to the conventional structure in which the n⁺-type wiring region 121 faces an entire area of the surface of the gate pad 114 (refer to FIG. 9), the displacement current, which causes punch-through of the n⁺-type wiring regions 41, may be reduced and thus, punch-through of the n⁺-type wiring regions 41 may be suppressed. Further, the n⁺-type wiring regions 41 are disposed in a stripped pattern, whereby even when punch-through occurs at the n⁺-type wiring regions 41, locations where punch-through occurs in the n⁺-type wiring regions 41 falls short of the entire surface of the region facing the entire surface of the gate pad 14. Thus, shoot-through current flowing between the drain electrode 15 and the source electrode wiring 13a may be reduced.

The n⁺-type wiring regions 41 has a function of drawing out hole current that flows in the p⁺-type high-concentration region 3 when the pn junction 8 between the p⁺-type high-concentration region 3 and the n-type current spreading region 2 is reverse biased, converting the hole current to an electric current, and discharging the electric current to the source electrode 13 via the source electrode wiring 13a. The n-type regions have extremely low sheet resistance as compared to the p-type regions, thereby facilitating current flow. In addition, the n-type regions have extremely low contact resistance as compared to the p-type regions, thereby facilitating fixing the n-type regions to the potential of the source electrode 13. Thus, due to the n⁺-type wiring regions 41, the resistance value up to the source potential fixing point of the region directly beneath the gate pad 14 decreases and the hole current flowing in the p⁺-type high-concentration region 3 may be rapidly discharged to the source electrode 13 via the source electrode wiring 13a.

The n⁺-type wiring regions 41 may be electrically connected to the source electrode wiring 13a via the p⁺⁺-type wiring region 5. While both ends of each of the n⁺-type wiring regions 41 in the longitudinal direction in which the n⁺-type wiring regions 41 extend in a striped pattern (linearly) may preferably be connected to the source electrode wiring 13a (not depicted), only one end in the longitudinal direction may be connected to the source electrode wiring 13a (FIG. 6). The longitudinal direction of the n⁺-type wiring regions 41 may be suitably changed independent of the layout of the MOS gates (the gate electrodes 34). The layout of the source electrode wiring 13a is determined so that the source electrode wiring 13a and the gate metal wiring layer (gate runner), which are disposed along at least one side of the periphery of the gate pad 14, are apart from each other.

For example, the gate metal wiring layer is disposed along the outer periphery of the source electrode 13 so as to surround the periphery of the source electrode 13 in a same shape, in a plan view, as that of the source electrode 13. In this instance, between the source electrode 13 and the gate pad 14, the gate metal wiring layer surrounds the three sides of the gate pad 14 facing the source electrode 13. Thus, the source electrode wiring 13a is disposed close to the one side of the gate pad 14 not facing the source electrode 13 and only one of the ends of each of the n⁺-type wiring regions 41 in the longitudinal direction thereof is connected to the source electrode wiring 13a and thus, the design of the layout of the gate metal wiring layer and the source electrode wiring 13a is facilitated.

Further, in an instance in which both ends of each of the n⁺-type wiring regions 41 in the longitudinal direction thereof are connected to the source electrode wiring 13a, each of the n⁺-type wiring regions 41 is connected to the source electrode wiring 13a in a vicinity of a pair of opposite sides of the gate pad 14. In this instance, the source electrode wiring 13a may be disposed between the source electrode 13 and the gate pad 14 (i.e., the n⁺-type wiring regions 41 extends in a striped pattern in a horizontal direction in FIG. 1). Alternatively, the source electrode wiring 13a may be disposed in a vicinity of each of opposite sides of the gate pad 14, including the one side not facing the source electrode 13 (i.e., the n⁺-type wiring regions 41 extend in a striped pattern in a vertical direction in FIG. 1).

In the second embodiment, in an instance in which between the n⁺-type wiring regions 41 and the p-type base region 4 is free of the p⁺⁺-type contact region 6, punch-through occurs in the n⁺-type wiring regions 41 at the moment that high voltage is applied to the drain electrode 15 and a large current flows from the drain electrode 15 to the source electrode wiring 13a. Thus, while a thickness t15 of each of the n⁺-type wiring regions 41 may be as deep as the p⁺⁺-type contact region 6 is present between the n⁺-type wiring regions 41 and the p-type base region 4, preferably, the n⁺-type wiring regions 41 may be as thin as possible. The thickness t15 of the n⁺-type wiring regions 41 is, for example, about 0.3 μm or less and, for example, preferably, may be about 0.2 μm.

As described above, according to the second embodiment, between the front surface of the semiconductor substrate and the p⁺⁺-type contact region, the n⁺-type wiring regions, which are fixed to the potential of the source electrode, are selectively disposed directly beneath the gate pad. The n-type region has an extremely low sheet resistance as compared to the p-type regions. Thus, due to the n⁺-type wiring regions, which have a low resistance, the resistance value up to the source potential fixing point of the region directly beneath the gate pad decreases.

In other words, when voltage that is positive with respect to the source electrode is applied to the drain electrode, hole current that flows in the p⁺-type high-concentration region, which is directly beneath the gate pad and has a high resistance, is drawn out, converted into an electrical current by the n⁺-type wiring regions of a low resistance and is discharged to the source electrode, whereby the p⁺-type high-concentration region, which has a high resistance, may be rapidly depleted. Thus, effects similar to those of the first embodiment may be obtained.

In the foregoing, the present invention is not limited to the embodiments described and various modifications within a range not departing from the spirt of the invention are possible. For example, the n⁺-type regions that are electrically floating in the first embodiment may be disposed regularly with respect to the gate pad in the depth direction and may be disposed in a striped pattern extending in a direction parallel to the front surface of the semiconductor substrate. Further, the source electrode wiring may be omitted and the p⁺⁺-type wiring region of the first embodiment may be connected directly to the source electrode, or the p⁺⁺-type wiring region and the n⁺-type wiring regions of the second embodiment may be connected directly to the source electrode. Further, the present invention is not limited to a SiC-MOSFET and is applicable to a silicon carbide semiconductor device that includes a MOS gate structure and a gate pad such as, for example, a SiC-insulated gate bipolar transistor (SiC-IGBT).

According to the invention described above, when voltage that is positive with respect to the first electrode is applied to the second electrode, holes in the fourth semiconductor region of a high resistance and directly beneath the gate pad recombine with electrons in the sixth semiconductor regions and thereby disappear, whereby ionization of acceptors in the fourth semiconductor region progresses and the fourth semiconductor region may be rapidly depleted. As a result, even when the voltage applied to the second electrode rapidly increases due to high-speed switching, steep dV/dt, etc., a depletion layer is formed by the pn junction between the first semiconductor region and the fourth semiconductor region directly beneath the gate pad 3 and the pn junction is fixed to the potential of the first electrode. Thus, application of high electric field to the insulating film beneath the gate pad due to high voltage applied to the second electrode may be prevented.

The silicon carbide semiconductor device according to the present invention achieves an effect in that dielectric breakdown capability may be enhanced.

As described, the silicon carbide semiconductor device according to the present invention is useful for power semiconductor devices used in power converting equipment, power source devices of various types of industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
an insulated gate having a metal-oxide-semiconductor structure;
a semiconductor substrate containing silicon carbide and having a first main surface and a second main surface that are opposite to each other;
a first semiconductor region of a first conductivity type, provided in the semiconductor substrate;
a second semiconductor region of a second conductivity type, provided between the first main surface of the semiconductor substrate and the first semiconductor region;
a third semiconductor region of the second conductivity type, selectively provided between the first main surface of the semiconductor substrate and the second semiconductor region, the third semiconductor region having an impurity concentration that is higher than an impurity concentration of the second semiconductor region;
a device structure having the insulated gate, wherein a current that passes through a pn junction between the second semiconductor region and the first semiconductor region flows in the device structure;
a gate pad provided at the first main surface of the semiconductor substrate via an insulating film, the gate pad being electrically connected to a gate electrode constituting the metal of the insulated gate, an entire surface of the gate pad facing the third semiconductor region via the insulating film;
a first electrode provided at the first main surface of the semiconductor substrate, apart from the gate pad, the first electrode being electrically connected to the second semiconductor region and the third semiconductor region;
a second electrode provided at the second main surface of the semiconductor substrate;
a fourth semiconductor region of the second conductivity type, provided between the second semiconductor region and the first semiconductor region, the fourth semiconductor region facing the gate pad in a depth direction of the semiconductor device, and having an impurity concentration that is higher than the impurity concentration of the second semiconductor region and lower than the impurity concentration of the third semiconductor region;
a fifth semiconductor region of the second conductivity type, penetrating through the second semiconductor region in the depth direction of the semiconductor device and reaching the fourth semiconductor region, the fifth semiconductor region electrically connecting the first electrode to the fourth semiconductor region, and having an impurity concentration that is higher than the impurity concentration of the fourth semiconductor region; and
a plurality of sixth semiconductor regions of the first conductivity type, selectively provided between the first main surface of the semiconductor substrate and the third semiconductor region, each sixth semiconductor region facing the gate pad in the depth direction of the device.

2. The silicon carbide semiconductor device according to claim 1, wherein each of the plurality of sixth semiconductor regions is electrically floating.

3. The silicon carbide semiconductor device according to claim 2, wherein the plurality of sixth semiconductor regions is disposed in a matrix pattern.

4. The silicon carbide semiconductor device according to claim 1, wherein the plurality of sixth semiconductor regions is electrically connected to the first electrode.

5. The silicon carbide semiconductor device according to claim 4, wherein the plurality of sixth semiconductor regions is disposed in a striped pattern as a plurality of stripes each extending in a direction parallel to the first main surface of the semiconductor substrate, each of the plurality of sixth semiconductor regions having an end in a longitudinal direction thereof that is electrically connected to the first electrode.

6. The silicon carbide semiconductor device according to claim 1, wherein an impurity concentration of the first conductivity type of the plurality of sixth semiconductor regions is lower than the impurity concentration of the second conductivity type of the third semiconductor region.

7. The silicon carbide semiconductor device according to claim 1, wherein the impurity concentration of the fourth semiconductor region is at least 1×10¹⁹/cm³.

8. The silicon carbide semiconductor device according to claim 1, wherein a width of the gate pad is at least 100 μm.
